(19) United States
(12) Patent Application Publication
(10) Pub. No.: US 2017/0009334 A1
(43) Pub. Date: Jan. 12, 2017

(54) HARD ALUMINUM OXIDE COATING FOR VARIOUS APPLICATIONS

(71) Applicant: Rubicon Technology, Inc., Bensenville, IL (US)

(72) Inventors: John P. CIRALDO, Elgin, IL (US); Jonathan B. LEVINE, Chicago, IL (US); Hasitha GANEGODA, Bensenville, IL (US)

(21) Appl. No.: 14/795,590

(22) Filed: Jul. 9, 2015

(51) Int. Cl. C23C 14/08; C23C 14/34

(52) U.S. Cl. CPC C23C 14/081; C23C 14/3442; C23C 14/34

(57) ABSTRACT

A structure for a hardened optically transmissive material including a hard coating is provided. The structure for the hardened optically transmissive material including the hard coating includes a substrate, and an aluminum oxide film disposed over the substrate, wherein the aluminum oxide film is grown to between 100 nanometers (nm) and 5 microns (um). The aluminum oxide film demonstrates a hardness greater than 10 gigapascals (GPa) as measured by nanoindentation, and the aluminum oxide film exhibits a transparency value such that at least 84 percent of light waves transmit through the aluminum oxide film for light waves within a range of wavelengths.

### BACKGROUND

1. Field

The present disclosure relates to a hard aluminum oxide coating as well as a system and method for coating a material with the hard aluminum oxide coating to create a hardened material that may be optically transmissive.

2. Description of the Related Art

There are many applications for use of glass including applications in the electronics area. Several mobile devices such as cell phones and computers may employ glass screens that may be configured as a touch screen. These glass screens can be prone to breakage or scratching Some mobile devices use hardened glass, such as ion exchange glass, to reduce surface scratching or the likelihood of cracking. However, an even harder and more scratch-resistant surface would be an improvement over the currently available materials.

Reducing scratching and cracking tendencies would provide longer life products. Moreover, a reduction in the incidents of accelerated loss of useful life of various glass-based products would be advantageous; especially those products that are handled frequently by users and prone to accidental dropping. Thus, a composition and a process that provide better resistance to cracking and scratching would be beneficial.

### SUMMARY

Exemplary embodiments may overcome one or more of the above disadvantages and other disadvantages not described above.

According to one non-limiting example of the disclosure, a hard coating, as well as a system and method for coating a material with the hard coating is provided to create a hardened optically transmissive material to provide an improved transparent, scratch-resistant surface.

According to an aspect of an exemplary embodiment, there is provided a structure for a hardened optically transmissive material including a hard coating. The structure includes a substrate, and an aluminum oxide film disposed over the substrate, wherein the aluminum oxide film is grown to between 100 nanometers (nm) and 5 microns (um), wherein the aluminum oxide film demonstrates a hardness greater than 10 gigapascals (GPa) as measured by nanoindentation, and wherein the aluminum oxide film exhibits a transparency value such that at least 84 percent of light waves transmit through the aluminum oxide film for light waves within a range of wavelengths.

According to one or more embodiments, the structure including the hard coating may further include an intermediary layer disposed between the aluminum oxide film and the substrate. The intermediary layer may be selected from a group consisting of a transparent conductor, a bezel paint, and a combination thereof. The intermediary layer may be structured such that the aluminum oxide film grows on the intermediary layer with a crystal structure and a preferred orientation of [0001].

According to an embodiment, the intermediary layer has a Coefficient of Thermal Expansion (CTE) that is between CTE values of the substrate and the aluminum oxide film. According to another embodiment, the intermediary layer has a compensating Coefficient of Thermal Expansion (CTE) that is lower than CTE values of the substrate and the aluminum oxide film. According to another embodiment, the intermediary layer has a compensating Coefficient of Thermal Expansion (CTE) that is higher than CTE values of the substrate and the aluminum oxide film.

According to one or more embodiments, the intermediary layer is a metal oxide, and wherein the intermediary layer is between 100 nm and 200 nm thick. The intermediary layer may be a metal oxide selected from a group consisting of titanium-oxide, zinc-oxide, magnesium-oxide, chromium-oxide, and nickel-oxide.

In certain embodiments, the vapor deposition used is one selected from a group consisting of physical vapor deposition (PVD) and chemical vapor deposition (CVD). PVD includes at least cathodic arc deposition, electron beam physical vapor deposition, evaporative deposition, pulsed laser deposition, sputtering deposition, and thermal deposition. CVD includes at least atmospheric pressure CVD (APCD), low-pressure CVD (LPCVD), ultrahigh vacuum CVD (UHVCVD), aerosol assisted CVD (AACVD), direct liquid injection CVD (DLICVD), microwave plasma-assisted CVD (MPCVD), plasma-enhanced CVD (PECVD), atomic-layer CVD (AACVD), combustion CVD (CCVD), hot filament CVD (HFCVD), hybrid physical-chemical CVD (HPCVD), metalorganic CVD (MOCVD), rapid thermal CVD (RTCVD), vapor-phase epitaxy (VPE), and photo-initiated CVD (PICVD). In certain embodiments, the vapor deposition of the aluminum atoms and the oxygen atoms is at a two to three ratio, respectively, with a ratio variance of less than or equal to 5%.

In certain embodiments the substrate is non-transparent. In some embodiments the aluminum oxide film disposed over the substrate is done by vapor deposition of aluminum atoms with oxygen atoms. In certain embodiments, the substrate is selected from a group consisting of sapphire, soda lime glass, aluminosilicate glass, borosilicate glass, Yttria-stabilized zirconia (YSZ), quartz, and a combination thereof. According to other embodiments, the substrate is selected from a group consisting of a metal, a plastic, a metal alloy, steel, aluminum, titanium, and a combination thereof.

In certain embodiments, the range of wavelengths is greater than 400 nm and less than 900 nm. In other embodiments, the range of wavelengths is greater than 900 nm and less than 3300 nm.

In certain embodiments, the aluminum oxide film is grown to 1 um. The aluminum oxide film may demonstrate a hardness greater than 14 gigapascals (GPa), and where the hardness is measured by nanoindentation with a Berkovich probe tip. The aluminum oxide film may demonstrate a hardness greater than 20 gigapascals (GPa), and where the hardness is measured by nanoindentation with a Berkovich probe tip.

According to certain embodiments, the hard coating may further include foreign dopant atoms mixed into the aluminum oxide film that strengthen the hard coating, where the foreign dopant atoms are selected from a group consisting of gallium, indium, carbon, and a combination thereof. According to other embodiments, the hard coating further includes foreign dopant atoms mixed into the aluminum oxide film that adjust a coloration of the aluminum oxide film, where the foreign dopant atoms are selected from a group consisting of chromium, titanium, iron, beryllium, carbon, and a combination thereof. According to certain embodiments, the aluminum oxide film forms in a corundum crystal structure.

According to an aspect of another exemplary embodiment, there is provided a method of creating a hard coating. The method includes generating aluminum oxide by setting a chamber pressure, setting a substrate temperature, creating a partial pressure of a gas in the chamber, and exposing a target within the chamber to an ionized gas. The method also includes depositing aluminum oxide by vapor deposition over a substrate in the chamber, and stopping the vapor deposition of the aluminum oxide once an aluminum oxide film disposed over the substrate is between 100 nm and 5 um.

In certain embodiments, ionization is facilitated by at least one selected from a group consisting of a biasing power, a gas, a high temperature, and a combination thereof. The target is one selected from a group consisting of an aluminum target and an aluminum oxide target. The gas is one selected from a group consisting of an inert gas, a noble gas, oxygen gas, argon gas, and a combination thereof.

In certain embodiments depositing aluminum oxide by vapor deposition over the substrate includes adjusting the partial pressure of the gas in the chamber during vapor deposition, wherein the gas is oxygen, tuning a sputtering rate of particles from the target by modifying the ionization near the target, and controlling the partial pressure of the oxygen and the sputtering rate of particles to achieve a ratio of two aluminum atoms for every three oxygen atoms.

In accordance with one or more embodiments, the method may further include depositing the aluminum oxide film over an intermediary layer disposed between the substrate and the aluminum oxide film. In certain embodiments, the intermediary layer is a metal oxide, wherein the intermediary layer is between 100 nm and 200 nm thick, wherein the intermediary layer has a coefficient of thermal expansion (CTE) that is different from CTE values of the substrate and the aluminum oxide film, and wherein the intermediary layer is structured such that the aluminum oxide film grows on the intermediary layer with a crystal structure and a preferred orientation of [0001]. In certain embodiments, the intermediary layer is a metal oxide selected from a group consisting of titanium-oxide, zinc-oxide, magnesium-oxide, chromium-oxide, nickel-oxide, and a combination thereof.

In accordance with one or more embodiments, the method may further include tuning the partial pressure of oxygen to accommodate for variability of deposition resulting from a non-constant voltage bias.

According to an aspect of another exemplary embodiment, there is provided a system for creating hardened optically transmissive material that includes a hard coating. The system includes a chamber that creates a partial pressure of oxygen atoms, a support device that secures a substrate within the chamber, and an excitation device including a heating element and a biased current power supply, wherein the excitation device releases energetic and unbounded aluminum atoms from an aluminum target by heating the aluminum target and applying a biased current across the aluminum target, and wherein the energetic and unbounded aluminum atoms are released into the chamber creating a deposition beam that reacts with the oxygen atoms to create an aluminum oxide film over a surface of the substrate. The chamber, support device, and excitation device may be made of stainless steel.

Other aspects and advantages of the invention will be apparent from the following description and the appended claims.

### BRIEF DESCRIPTION OF DRAWINGS

The following figures are included to illustrate certain aspects of the present disclosure, and should not be viewed as exclusive embodiments. The subject matter disclosed is capable of considerable modifications, alterations, combinations, and equivalents in form and function, without departing from the scope of this disclosure.

FIG. 1 is a block diagram of a system configured to perform reactive thermal evaporation in accordance with a disclosed embodiment.

FIG. 2 is a block diagram of a system configured to perform reactive thermal evaporation in accordance with a disclosed embodiment.

FIG. 3 is a block diagram of a system configured to perform sputtering deposition in accordance with a disclosed embodiment.

FIG. 4 is a block diagram of a system configured to perform sputtering deposition in accordance with a disclosed embodiment.

FIG. 5 is a flow diagram of a process for creating an aluminum oxide enhanced substrate in accordance with a disclosed embodiment.

FIG. 6 is a flow diagram of a process for creating an aluminum oxide enhanced substrate in accordance with a disclosed embodiment.

FIGS. 7A through 7C are diagrams depicting combinations of the substrate, intermediary layer, and the hard optical coating in accordance with the disclosed embodiments.

FIG. 8 is a table that contains the properties of deposited hard optical coatings/films and their direct relationship to temperature and film thickness in accordance with the disclosed embodiments.

FIG. 9 is a table that contains coloration dopants and their corresponding amounts to create certain colors in accordance with the disclosed embodiments.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. The progression of processing steps and/or operations described is an example; however, the sequence of and/or operations is not limited to that set forth herein and may be changed as is known in the art, with the exception of steps and/or operations necessarily occurring in a particular order. Particularly, although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously. In some applications, not all steps may be required. In addition, respective descriptions of well-known functions and constructions may be omitted for increased clarity and conciseness.

Additionally, exemplary embodiments will now be described more fully hereinafter with reference to the accompanying drawings. The exemplary embodiments may, however, be embodied in many different forms and should not be construed as being limited to the embodiments set forth herein. These embodiments are provided so that this disclosure will be thorough and complete and will fully convey the exemplary embodiments to those of ordinary skill in the art. The scope is defined not by the detailed description but by the appended claims. Like numerals denote like elements throughout.

Terms such as “first” and “second” may be used to distinguish one component from another. Additionally, it will be understood that when an element is referred to as being “connected to” another element, it can be directly connected to the other element or intervening elements may also be present. In contrast, when an element is referred to as being “directly connected to” another element, no intervening elements are present. Meanwhile, other expressions describing relationships between components such as “between”, “immediately between” or “adjacent to” and “directly adjacent to” may be construed similarly.

Singular forms “an” and “the” in the present disclosure are intended to include the plural forms as well, unless the context clearly indicates otherwise. It will be further understood that terms such as “including” or “having,” etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

It will be understood that the terms “includes,” “comprises,” “including,” and/or “comprising,” when used in this specification, specify the presence of stated elements and/or components, but do not preclude the presence or addition of one or more elements and/or components thereof. As used herein, the term “module” refers to a unit that can perform at least one function or operation and may be implemented utilizing any form of hardware, software, or a combination thereof.

Devices that are in communication with each other need not be in continuous communication with each other, unless expressly specified otherwise. In addition, devices that are in communication with each other may communicate directly or indirectly through one or more intermediaries. When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

Although the terms used herein are generic terms which are currently widely used and are selected by taking into consideration functions thereof, the meanings of the terms may vary according to the intentions of persons skilled in the art, legal precedents, or the emergence of new technologies. Furthermore, some specific terms may be randomly selected by the applicant, in which case the meanings of the terms may be specifically defined in the description of the exemplary embodiment. Thus, the terms should be defined not by simple appellations thereof but based on the meanings thereof and the context of the description of the exemplary embodiment. As used herein, expressions such as “at least one of,” when preceding a list of elements, modify the entire list of elements and do not modify the individual elements of the list.

According to one or more embodiments, a number of different methods can be used to adhere and grow the aluminum oxide layer onto a substrate or intermediary layer including different Chemical Vapor Deposition (CVD) techniques and Physical Vapor Deposition (PVD) techniques such as sputtering techniques and reactive thermal evaporation. The use of aluminum oxide films, as opposed to full sapphire windows, may provide a material cost saving by not having to use as much of the specific aluminum oxide and may also provide additional cost savings by eliminating the need to cut, grind, or polish sapphire, which is difficult and costly.

Many different systems may be used to adhere and grow an aluminum oxide layer to a substrate and/or intermediary layer. Particularly, according to one or more exemplary embodiments, a number of systems may be used to create the aluminum oxide film/layer implementing vapor deposition techniques including Physical Vapor Deposition (PVD) and Chemical Vapor Deposition (CVD) processes. Thus, a structure for a hardened optically transmissive material including a hard optical film can be grown by a physical vapor deposition (PVD) process such as sputtering or thermal deposition or by a chemical vapor deposition (CVD) process or a combination thereof.

For example, some variants of PVD that may be used include: (a) cathodic arc deposition in which a high-power electric arc discharged at the target (source) material blasts away some into highly ionized vapor to be deposited; (b) electron beam physical vapor deposition in which the material to be deposited is heated to a high vapor pressure by electron bombardment in “high” vacuum and is transported by diffusion to be deposited by condensation; (c) evaporative deposition (sometimes called thermal deposition) in which the material to be deposited is heated to a high vapor pressure by electrically resistive heating in “low” vacuum; (d) pulsed laser deposition in which a high-power laser ablates material from the target into a vapor; and (e) sputter deposition in which a glow plasma discharge, which is usually localized around the “target” by a magnet, bombards the material sputtering some away as a vapor for subsequent deposition.

Some examples of CVD variants that may be used include atmospheric pressure CVD (APCD), low-pressure CVD (LPCVD), ultrahigh vacuum CVD (UHVCVD), aerosol assisted CVD (AACVD), direct liquid injection CVD (DLICVD), microwave plasma-assisted CVD (MPCVD), plasma-enhanced CVD (PECVD), atomic-layer CVD (ALCVD), combustion CVD (CCVD), hot filament CVD (HFCVD), hybrid physical-chemical CVD (HPCVD), metalorganic CVD (MOCVD), rapid thermal CVD (RTCVD), vapor-phase epitaxy (VPE), and photo-initiated CVD (PICVD).

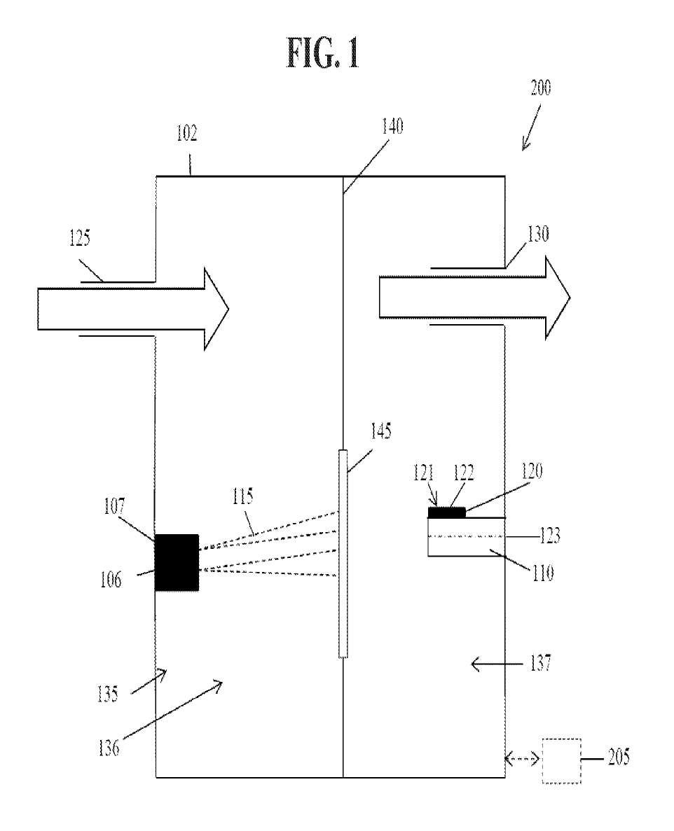

According to an aspect of the disclosure, FIG. 1 illustrates a block diagram of an example of a system 200 configured to perform thermal/evaporative deposition in accordance with a disclosed embodiment. Thermal/evaporative deposition is also commonly known as reactive thermal evaporation.

In the depicted embodiment, the system 200 includes an evacuation chamber 102. In one embodiment, the evacuation chamber 102 may include a partition 140 that is used to create two parts, a first part 136 and a second part 137, within the evacuation chamber 102.

As will be further discussed, the system 200 is configured to create partial pressure of process gas 135, including molecular or atomic oxygen, within the first part 136 of the evacuation chamber 102. For instance, in one embodiment, a process gas inlet 125 enables gas to enter into the first part 136 of the evacuation chamber 102. In one embodiment, the first part 136 includes a crucible 106 containing substantially pure aluminum 107. The system 200 is configured to heat the crucible 106 to a point that the aluminum 107 begins to evaporate. The aluminum 107 may be used to create energized aluminum atoms for producing a controlled beam 115 of aluminum atoms and/or aluminum oxide molecules.

The second part 137 may include a stage 110 and a substrate 120. The stage 110 may be configured to be heated (or cooled) by a heat or cooling source 123 which may also be called a heat or cooling device 123. The stage 110 may be configured to move in any one or more dimensions of 3-D space, including configured to be rotatable, movable in an x-axis, movable in a y-axis and/or movable in a z-axis. A gas exhaust 130 enables gas to escape from the second part 137 of the evacuation chamber 102.

In one embodiment, the partition 140 includes an aperture or shutter 145 that is configured to open and close. The partition 140 is configured to prevent energetic aluminum atoms and aluminum oxide molecules in the first part 136 of the evacuation chamber 102 from prematurely accessing the second part 137 of the evacuation chamber 102.

In accordance with the disclosed embodiments, a transparent and shatter-resistant substrate 120, such as, e.g., glass, quartz, or the like, may be placed onto the stage 110. In some embodiments, the substrate 120 may be a planar material or a non-planar material. The substrate 120 may have one or more surfaces that may be subject to treatment. The substrate 120 may be soda-lime glass, borosilicate glass, ion exchange glass, aluminosilicate glass, yttria-stabilized zirconia (YSZ), transparent plastic, or other shatter-resistant transparent window material. In some applications, the substrate 120 may be embodied in multiple dimensions, e.g., to include surfaces oriented in three dimensions that may be treated by the matrix creating process.

The substrate 120 is then heated within the evacuation chamber 102. Process gases are permitted to flow into the evacuation chamber 102 such that a controlled partial pressure is achieved. These gases may contain oxygen either in atomic or molecular form, and may also contain inert gases such as argon. Upon achieving the desired partial pressure, a deposition beam 115 of aluminum atoms, aluminum oxide molecules, or a combination thereof (hereinafter referred to as deposition beam 115) may be introduced such that the substrate 120 is exposed to the deposition beam 115. The deposition beam 115 may be a cloud-like beam. A matrix comprising of an aluminum oxide layer 121, which may also be called an aluminum oxide coating 121 or an aluminum oxide film 121, and the transparent and shatter-resistant substrate 120 is produced through a reactive thermal evaporation deposition. A deposition layer(s) several nanometers to several hundred microns thick can be achieved depending on the process parameters and duration. Process duration can be several minutes to several hours. By controlling the aluminum atom flux and oxygen partial pressure, the properties of the coated film can be tailored to maximize the film's scratch resistance. In one embodiment, adjusting an orientation or position of the substrate 120 relative to a deposition beam 115 adjusts an exposure amount of the energetic aluminum atoms and aluminum oxide molecules to the substrate 120. This may also permit coating of the aluminum oxide layer 121 to select or additional sections of the substrate 120.

As shown, and in accordance with an embodiment, the substrate 120 may be separated from the aluminum 107 while the aluminum 107 is being heated during the first stage of the process by the partition 140 and with the shutter 145 being in a closed position. The partition 140 and the shutter 145 prevent aluminum 107 vapors and/or aluminum oxide vapors from reaching the substrate 120 prematurely. Once sufficient temperature for the aluminum 107 has been reached (for example, about 1350° C.), oxygen may be permitted to flow from the gas inlet 125 into the evacuation chamber 102 (i.e., into both parts 136 and 137), where the stable oxygen partial pressure 135 may be achieved. This gas may contain oxygen either in atomic or molecular form, and may also contain inert gases such as argon.

Upon achieving the predetermined stable oxygen partial pressure 135, the shutter 145 may be opened, exposing the substrate 120 to the beam of energetic and unbounded aluminum atoms 115 (which might include some aluminum oxide molecules) in the presence of oxygen. The gases including energetic aluminum atoms and/or aluminum oxide molecules 115 of the first part 136 may then access the second part 137. The shutter 145 may be opened approximately when the stable oxygen partial pressure 135 has been achieved, but may vary. Typically, the pressurized environment of oxygen is created before or proximate to opening the shutter 145. The oxygen and aluminum react, forming aluminum oxide on or near the substrate 120 creating and growing the aluminum oxide film 121 at the substrate surface 122. Gas from the process may exhaust through the gas exhaust 130.

According to another embodiment, the substrate 120 may not be separated from the aluminum 107 while the aluminum 107 is being heated during the first stage of the process. Specifically, the partition 140 and shutter 145 are not included in this embodiment. The aluminum oxide vapors and the aluminum vapors can be controlled by the rate at which the select temperature is reached as well as careful control of the specific partial pressure of oxygen 135 and flow within the chamber 102. Other elements that may be adjusted to help control the deposition includes changing the arrangement of the substrate 120 and the aluminum 107 within the chamber 102 as well as changing the shape and/or size of any one of the chamber 102, the substrate 120, and the aluminum target 107.

The substrate 120 may be exposed to the deposition beam of aluminum atoms 115 and/or aluminum oxide molecules 115, and the exposure stopped based on a predetermined parameter such as, e.g., a predetermined time period and/or a predetermined depth of layering of aluminum oxide on the substrate being achieved.

In one embodiment, the aluminum atoms 115 form aluminum oxide (Al2O3) molecules in response to being exposed to oxygen within the evacuation chamber 102. The aluminum oxide (Al2O3) molecules then adhere to the substrate surface 122 forming a matrix comprising a scratch-resistant aluminum oxide film 121 that is in contact with and is coating at least one substrate surface 122. If the deposition beam 115 is not sufficiently large enough to homogeneously cover the top substrate surface 122, the substrate 120 itself may be moved within the deposition beam 115, such as, e.g., through movement of the stage 110 which may be controlled to move up, down, left, right, and/or rotate, to allow an even coating. In some implementations, the crucible 106 with the aluminum 107 may be moved to change orientation of the deposition beam 115.

Moreover, the substrate 120 may be heated (or cooled) by heat or cooling device 123 sufficiently to allow mobility of aluminum and aluminum oxide particles on the surface 122 of the substrate 120, allowing for improved quality of the matrix generation. The deposited film 121 formed at the surface 122 of the substrate 120 chemically and/or mechanically adheres to the substrate surface 122 which creates a bond sufficiently strong enough to prevent delamination of the aluminum oxide (Al2O3) with the substrate 120, creating a hard and strong surface 120 that is highly resistant to breaking and/or scratching. The deposited film 121 conforms to the surface 122 of the substrate 120. This may be useful to coat irregular or non-planar surfaces. This tends to result in a superior bond over, for example, laminate type techniques.

The system 200 may be used to coat a material (such as, e.g., the substrate 120, which may be glass, quartz, transparent plastic, or the like) with the aluminum oxide layer 121, according to principles of the disclosure. The system 200 may be employed to produce a very hard and superior scratch-resistant surface on glass or other substrates. For example, the system 200 may be used to transform a material such as soda-lime glass, borosilicate glass, ion exchange glass, alumina-silicate glass, yttria-stabilized zirconia (YSZ), transparent plastic, or other shatter-resistant transparent window material into a matrix comprising of the shatter-resistant bulk window with a scratch-resistant applied aluminum oxide coating resulting in a superior product for use in applications where a hard, break-resistant, scratch-resistant surface is beneficial. Such applications may include, e.g., consumer devices, optical lenses, watch crystals, electronic devices or scientific instruments, and the like.

A benefit provided by the resultant matrix surface of aluminum oxide film 121 of this disclosure includes superior mechanical performance, such as, e.g., improved scratch resistance, greater resistance to cracking compared to currently used materials such as traditional untreated glass, plastic, etc. Additionally, by using aluminum oxide coated on a substrate such as glass, rather than an entire sapphire window (i.e., a window comprising all sapphire), the cost may be reduced substantially, making the product available for widespread consumer usage.

According to an exemplary embodiment, system 200 components may be substantially made of a non-reactive and non-oxidizing material, or said another way; they may be made from a material that is inert to an oxidizing environment. For example, the system 200 and components may be made substantially of stainless steel. Particularly, the inner walls of the chamber 102, the partition 140, the shutter 145, the crucible 106, the stage 110, and the heating/cooling device 123 may all be made from stainless steel. This provides for a reduction in uncontrolled impurities being released and then included in the aluminum oxide film allowing for better control of properties such as hardness and coloration that may be imparted by impurities that may be selected to be included.

The growth rate of the aluminum oxide (Al2O3) deposited film 121 at the surface 122 may be tunable. The growth rate of the aluminum oxide (Al2O3) film layer 121 may be enhanced by reducing the distance between the aluminum 107 and the substrate 120. This may be achieved, for example, by moving the crucible 106 and/or moving the stage 110. The rate may be further enhanced by modification of the temperature of the source aluminum 107, thereby altering the flux of aluminum and aluminum oxide vapors; or by modifying the flow of oxygen into the chamber 102. Other techniques of modifying the growth rate may include altering the ambient pressure within the chamber 102, or by other techniques of altering the growth environment.

The substrate 120 may be exposed to the deposition beam 115, and the exposure stopped based on a predetermined parameter such as, e.g., a predetermined time period and/or a predetermined depth of layering of aluminum oxide on the substrate being achieved. In one aspect, the predetermined depth may be a thickness of aluminum oxide film layer 121 of less than about 1% of the thickness of the substrate. According to another embodiment, the aluminum oxide film layer 121 may be between 1% and 2% of the thickness of the substrate. In one aspect, the thickness of the deposited aluminum oxide film layer may be between about 10 nanometers (nm) and about 5 microns (um). In one aspect, the thickness of the deposited aluminum oxide film layer 121 may be less than about 10 microns. According to another embodiment, the aluminum oxide film may be between 100 nm and Sum.

A matrix comprising a scratch-resistant surface layer 121 several nanometers to several hundred microns thick grown atop a transparent and shatter-resistant substrate 120 can be achieved depending on the process parameters and duration. Process duration can be several minutes to several hours. By controlling the flux of aluminum atoms and/or aluminum oxide molecules and oxygen partial pressure, the properties of the matrix formed at the surface 122 can be tailored to maximize the scratch resistance.

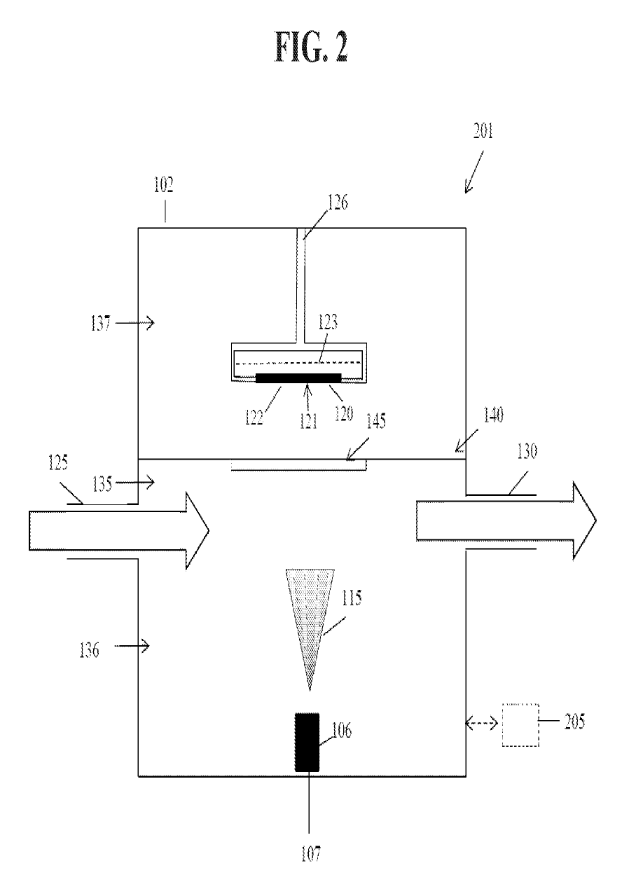

FIG. 2 is a block diagram of another exemplary embodiment of a system 201 configured to perform reactive thermal evaporation, the system 201 configured according to principles of the disclosure. The system 201 is similar to the system 200 of FIG. 1, except that the orientation of the substrate 120 and the substantially pure aluminum 107 may be oriented differently.

In this embodiment, a securing device 126 may be used to secure the substrate 120 so that the substrate is above the substantially pure aluminum 107. The aluminum atom and/or aluminum oxide beam 115 may be projected upwardly towards the substrate 120. In general, any suitable orientation of the substrate 120 in relation to the substantially pure aluminum 107 and/or beam 115 may be employed. The securing device 126 may be movable in any one or more axis. The securing device 126 may also be configured with the heat or cooling source device 123 to heat (or cool) the substrate 120.

In some implementations, the systems 200 and 201 may include a computer 205 to control the operations of the various components of the systems 200 and 201. For example, a computer 205 may control the heating of the aluminum 107. The computer 205 may also control the heat or cooling source device 123 to control heating (or cooling) of the substrate 120. The computer 205 may also control the motion of the stage 110, the securing mechanism 126 and may control the partial pressures of the evacuation chamber 102. The computer 205 may also control the tuning of the gap/distance between the aluminum 107 and the substrate 120. The computer 205 may control the amount of exposure duration of the deposition beam 115 with the substrate 120, perhaps based on, e.g., predetermined parameter such as time, or based on a depth of the aluminum oxide formed on the substrate 120, or amount/level of oxygen pressure employed, or any combination therefore. The process gas inlet 125 and gas outlet/exhaust 130 may include valves (not shown) for controlling the movement of the gases through the systems 200 and 201. The valves may be controlled by the computer 205. The computer 205 may include a database for storage of process control parameters and programming.

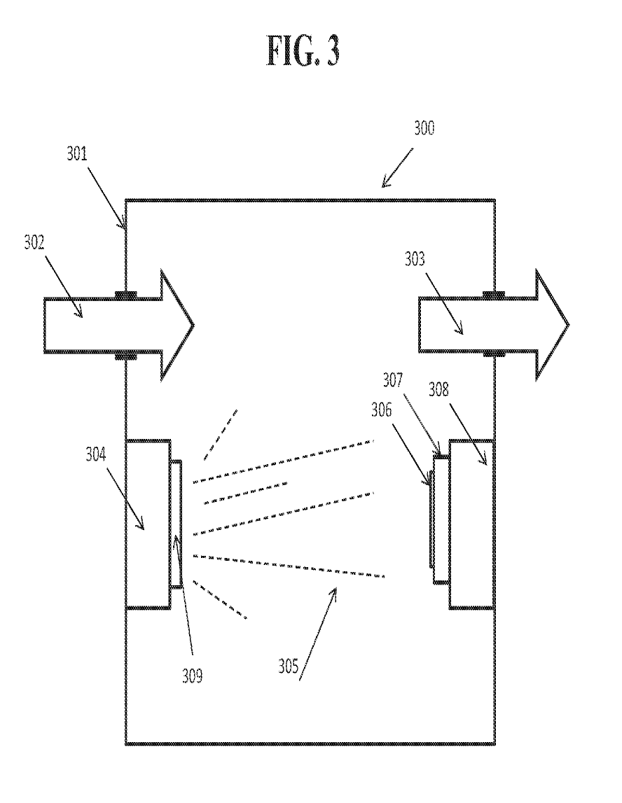

In one embodiment, as shown in FIG. 3, a sputtering technique is implemented using a voltage controlled reactive sputtering process device 300 to create an aluminum oxide thin film 306 on a substrate 307 that is being held in place on a platform 308 within a chamber 301. The sputtering technique is different from the above reactive thermal evaporation in that, instead of releasing aluminum using high temperatures, sputtering releases the aluminum atoms or ions through bombardment of energetic ions with the aluminum target 309 which causes the aluminum atoms or ions to be released. Specifically, according to one or more embodiments, a voltage excites a partial pressure of gas within the chamber 301, producing ions. These ions are then drawn to the target 309 by an electrical field, causing the ions to bombard the target 309. It is this bombardment that releases the atoms, ions, and/or molecules from the target 309. Additionally, the sputtering technique does not include separate internal cavities within the chamber 301. Within the chamber 301 a vacuum can be created initially and then the partial pressure of gas can be maintained, for example a partial pressure of oxygen and an inert gas such as argon. The platform 308 may include a heating or cooling source to control the temperature of the substrate 307. The voltage controlled reactive sputtering process creates the aluminum oxide thin film 306 by depositing using a magnetron sputtering device 304 which releases aluminum ions 305 from the aluminum target 309 by inducing the ion bombardment as described above. Particularly, the deposition process is controlled by a target voltage while target power is adjusted for the magnetron sputtering device 304 thereby controlling the release of aluminum ions 305. Further, a constant amount of oxygen gas is controlled such that the oxygen gas flows in through an inlet 302 and out through an outlet 303. Additionally, some dopant materials can be inserted through the gas inlet 302, and excess dopant materials can be evacuated using the outlet 303. The oxygen and aluminum ions interact creating the aluminum oxide which is then deposited onto the substrate to create the aluminum oxide film/layer 306.

In another embodiment, shown using FIG. 3, a sputtering technique is implemented using a voltage controlled reactive sputtering process device 300 to create an aluminum oxide thin film 306 on a substrate 307 that is being held in place on a platform 308 within a chamber 301. The sputtering technique is different from the above in that, instead of releasing aluminum atoms or ions which are then combined with the oxygen gas to create aluminum oxide, sputtering releases the aluminum oxide molecules directly by bombardment of ions from an energetic plasma drawn by an electrical bias to the aluminum oxide target 309 which causes the aluminum oxide molecules to be released. According to another embodiment, the target 309 may be an oxidized aluminum target which, when bombarded, will also directly release aluminum oxide molecules. Within the chamber 301 a vacuum can be created initially and then a partial pressure can be maintained using an inert gas such as argon and possibly some other gases such as oxygen can be included. The platform 308 may include a heating or cooling source to control the temperature of the substrate 307. The voltage controlled sputtering process creates the aluminum oxide thin film 306 by depositing using a magnetron sputtering device 304 which releases aluminum oxide molecules 305 from the aluminum oxide target 309. Particularly, the deposition process is controlled by a target voltage while target power is adjusted for the magnetron sputtering device 304 thereby controlling the release of aluminum oxide molecules 305. Further, a constant amount of gas is provided to control the partial pressure such that the gas flows in through an inlet 302 and out through an outlet 303. Additionally, some dopant materials can be inserted through the gas inlet 302, and excess dopant materials can be evacuated using the outlet 303. The aluminum oxide is then deposited onto the substrate to create the aluminum oxide film/layer 306.

In another embodiment, shown using FIG. 3, a sputtering technique is implemented using a noble gas bombardment sputtering process device 300 to create an aluminum oxide thin film 306 on a substrate 307 that is being held in place on a platform 308 within a chamber 301. The sputtering technique is different from the above embodiments in that, a sputtering of aluminum oxide molecules is done by bombarding a target 309, which may be an aluminum oxide target 309 or an aluminum target 309, with ions by using noble gases which causes the particles to be released. Within the chamber 301 a vacuum can be created initially and then a partial pressure can be maintained using an inert gas such as argon and possibly some other gases such as one or more of noble gases or oxygen can be included. The platform 308 may include a heating or cooling source to control the temperature of the substrate 307. The ion bombardment sputtering process creates the aluminum oxide thin film 306 by depositing using ion bombardment from the gases which releases particles such as aluminum oxide molecules 305 from, for example, the aluminum oxide target 309. Further, a constant amount of gas is provided to control the partial pressure such that the gas flows in through an inlet 302 and out through an outlet 303. Additionally, some dopant materials can be inserted through the gas inlet 302, and excess dopant materials can be evacuated using the outlet 303. The aluminum oxide is then deposited onto the substrate to create the aluminum oxide film/layer 306.

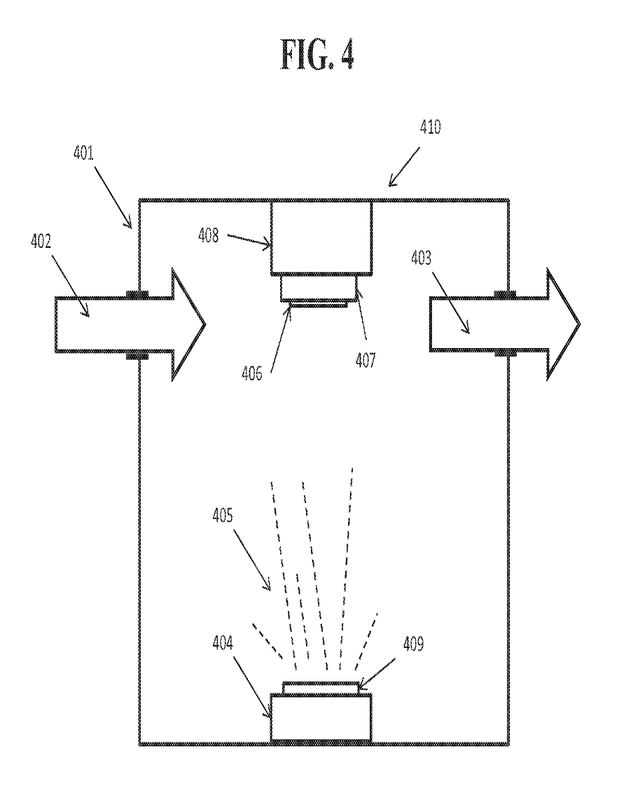

In another embodiment as shown in FIG. 4, a pulsed reactive sputtering technique is implemented using a system 410 to create an aluminum oxide film 406. The system 410 is similar to the system 300 of FIG. 3, except that the orientation of the substrate 407 and the aluminum target 309 may be oriented differently among other adjustments discussed below.

Particularly, the sputtering deposition of the aluminum oxide film 406 onto a substrate 407 is carried out with a magnetron sputtering device 404 which receives a pulsed power signal. The substrate 407 is held in position by a platform 408 that may also contain a heating or cooling source to control the substrate 407 temperature. An aluminum target 409 is placed in a chamber 401 that is evacuated using a high vacuum pump before sputtering creating a vacuum chamber 401. The high vacuum pump can be any one of a diffusion pump, a cryo pump, a turbo molecular pump, or any combination thereof. The sputtering atmosphere that is then created is a mixture of argon and oxygen. The oxygen is introduced in the vacuum chamber 401 through a gas inlet 402 and excess may then exit through an outlet 403 while being monitored and controlled by a mass flow meter. Argon is introduced using a valve that allows the flow of argon to pass in through the gas inlet 402 and out the outlet 403. The valve that allows the flow can be at least one of a piezoelectric valve or a needle valve. The oxygen flow, argon flow, and partial pressure can be adjusted providing pressure control of the vacuum chamber 401 during sputtering. Further, the oxygen gas is introduced immediate to the substrate 408 by the placement of the inlet 402 and the outlet 403. Additionally, some dopant materials can be inserted through the gas inlet 402 and excess can be evacuated using the outlet 403. The sputtering power is supplied by a pulsed square wave power supply which has adjustable pulse frequency, pulse time ratio, and amplitudes.

In both examples shown in FIGS. 3 and 4, the magnetron sputtering devices 304, 404 adjust the deposition rate and ratio of aluminum atoms 305, 405 to oxygen gas atoms such that the purity and consistency of the aluminum oxide films 306, 406 can be controlled. For example, the voltage rate can be controlled along with the rate of biasing the voltage such that the timing and excitation energy placed upon the aluminum targets 309, 409 are controlled so that the aluminum ions 305, 405 that are released are carefully controlled. Additionally, careful control of the temperature of the substrates 307, 407 can also help provide control over the oxidation rate that occurs in the chambers 301, 401 between the aluminum ions 305, 405 and the oxygen gas. Also, controlling the temperature of the aluminum targets 309, 409 is another factor which helps in controlling a rate of ion release from the aluminum targets 309, 409. Other variables that are controlled include the pressure within the chambers 301, 401, as well as controlling the specific temperature of the chambers 301, 401.

Similar to the system 200 discussed above, the systems 300, 410 may be used to coat a material (such as, e.g., the substrate 307, 407, which may be glass, quartz, transparent plastic, or the like) with an aluminum oxide layer 306, 406, according to principles of the disclosure. The systems 300,410 may be employed to produce a very hard and superior scratch-resistant surface on glass or other substrates. For example, the systems 300, 410 may be used to transform a material such as soda-lime glass, borosilicate glass, ion exchange glass, alumina-silicate glass, yttria-stabilized zirconia (YSZ), transparent plastic, or other shatter-resistant transparent window material into a matrix comprising of the shatter-resistant bulk window with a scratch-resistant applied aluminum oxide coating 306, 406 resulting in a superior product for use in applications where a hard, break-resistant, scratch-resistant surface is beneficial. Such applications may include, e.g., consumer devices, optical lenses, watch crystals, electronic devices or scientific instruments, and the like.

A benefit provided by the resultant matrix surface of aluminum oxide film 306, 406 of this disclosure includes superior mechanical performance, such as, e.g., improved scratch resistance, greater resistance to cracking compared to currently used materials such as traditional untreated glass, plastic, etc. Additionally, by using the aluminum oxide film 306, 406 coated on the substrate 407 such as glass, rather than an entire sapphire window (i.e., a window comprising all sapphire), the cost may be reduced substantially, making the product available for widespread consumer usage. Additional benefits and advantages similar to those discussed above with regards to system 200 may also be provided by system 300, 410.

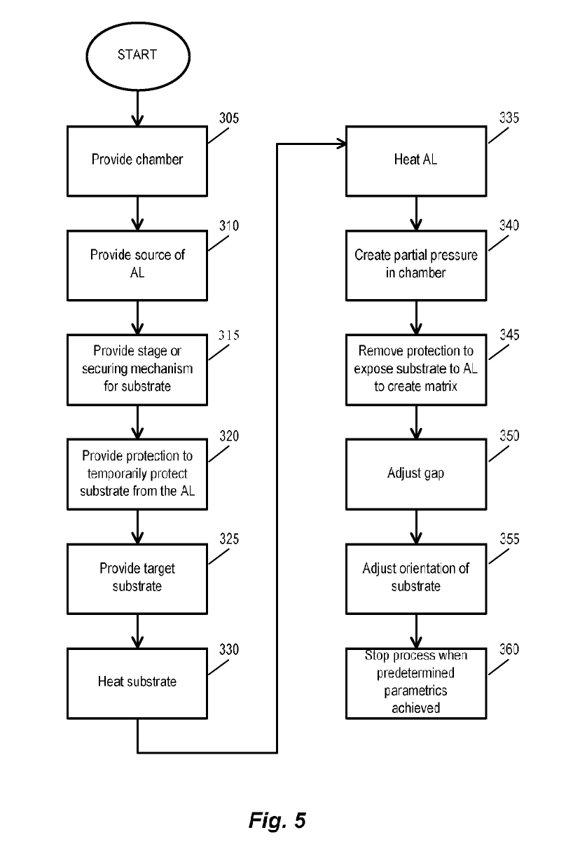

FIG. 5 illustrates a flow diagram in accordance with an exemplary embodiment of a process for creating an aluminum oxide enhanced substrate, the process performed according to principles of the disclosure. The process of FIG. 5 may be a type of reactive thermal evaporation, and can be used in conjunction with the systems 200, 201.

At step 305, a chamber such as, but not limited to, chamber 102, may be provided that is configured to permit a partial pressure to be created therein, and configured to permit a target substrate 120 such as, e.g., glass, borosilicate glass, aluminosilicate glass, ion-exchange glass, transparent plastic, or yttria-stabilized zirconia (YSZ) to be coated. Further, the chamber 102 may be configured to permit separation of the target substrate 120 from the aluminum 107 while the aluminum 107 is being heated, and configured to remove the separation during the process as described below.

At step 310, a source of aluminum such as, but not limited to, substantially pure aluminum, may be provided that enables energetic and unbounded aluminum atoms to be generated in the chamber 102.

At step 315, a securing device (e.g., securing device 126) or stage (e.g., stage 110) may be configured within the chamber 102. Both the stage 110 and/or securing device 126 may be configured to be rotatable. The stage 110 and/or securing device 126 may be configured to be moved in an x-axis, a y-axis and/or a z-axis.

At step 320, a protective barrier may be provided so that the target substrate, e.g., substrate 120, can be temporally protected from the beam of aluminum atoms and aluminum oxide molecules when created within the chamber. The protection may be the partition 140 that may be configured with, e.g., the aperture or shutter 145 that is configured to open in a first position and close in a second position. In the closed position, the aperture or shutter 145 separates the first part of the chamber, e.g., first part 136, from the second part, e.g., second part 137. The first part 136 may include the aluminum 107. The second part 137 may include the stage 110 or securing mechanism 126, and the target substrate 120.

At step 325, the target substrate 120 such as, e.g. glass, borosilicate glass, aluminosilicate glass, ion-exchange glass, transparent plastic, or YSZ, having one or more surfaces to be coated may be provided on the stage 110 or secured by the securing device 126, in the second part 137 of the chamber 102. At additional step 330, which may be optional, the target substrate 120 may be heated. At step 335, the substantially pure aluminum may be heated to produce aluminum atoms and/or aluminum oxide in the first part 136 of the chamber 102. The aluminum atoms may create a deposition beam 115 directed towards the partition 140. At step 340, a partial pressure of oxygen may be created in both parts 136 and 137 of the chamber. This may be achieved by permitting oxygen to flow into the chamber 102, perhaps under pressure. At step 345, the protection may be removed. This may be accomplished by opening the shutter 145 in partition 140. This permits the aluminum atoms and/or aluminum oxide of deposition beam 115 to reach the target substrate 120, which may form a deposition beam 115. The deposited film may be formed at the surface(s) of the target substrate 120. Further, the aluminum atoms may interact with the oxygen environment as they are directed towards the substrate 120 creating aluminum oxide molecules which are also directed toward the substrate 120.

According to an exemplary embodiment, at additional step 350, which may be optional, the gap or distance between the aluminum 107 source and the substrate 120 may be adjusted, typically reduced but may be increased, to control the rate of depositing of the aluminum oxide film on the target substrate 120. At additional step 355, which may be optional, the substrate 120 may be re-positioned by adjusting the stage 110 orientation. The stage 110 may be rotated or moved in any axis.

At step 360, a thin film is permitted to be created at one or more surfaces 122 of the substrate 120 as the aluminum atoms and/or aluminum oxide molecules coat and bond with the one or more surfaces 122. The process may be terminated when one or more predetermined parameter(s) are achieved such as time, or based on a depth of the aluminum oxide formed on the substrate 120, or amount/level of oxygen pressure employed, or any combination therefore. Moreover, a user may stop the process at any time.

This reactive thermal evaporation process of FIG. 5 has an advantage in that it does not utilize or require electrical fields and subsequent complexities typically found in other techniques such as reactive sputtering techniques which may also be implemented. According to another exemplary embodiment, a combinational approach may be implemented where the aluminum is heated as done in the thermal approach while also providing a voltage and current across the aluminum to excite additional aluminum atoms to release.

The steps of FIG. 5 may be performed by or controlled by a computer, e.g., computer 205 that is configured with software programming to perform the respective steps. FIG. 5 may also represent a block diagram of the components for executing the steps thereof. The components may include software executable by a computer processor (e.g., computer 205) for reading the software from a physical storage (a non-transitory medium) and executing the software that is configured to performing the respective steps. The computer processor may be configured to accept user inputs to permit manual operations of the various steps described.

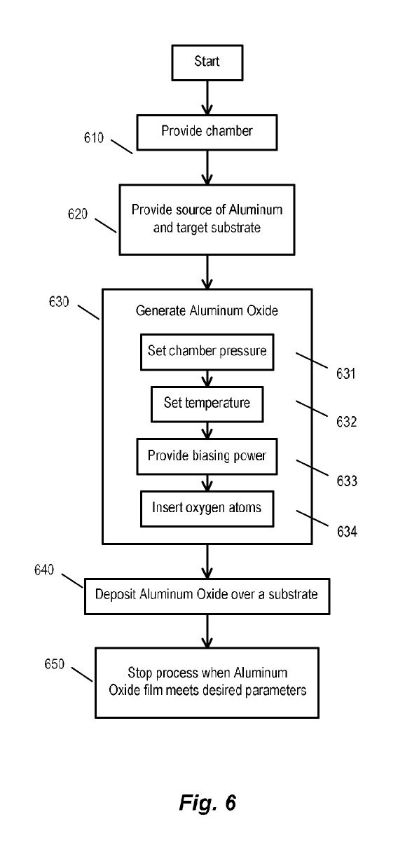

FIG. 6 illustrates a flow diagram in accordance with an exemplary embodiment of a process for creating an aluminum oxide enhanced substrate, the process performed according to principles of the disclosure.

The process of FIG. 6 is an example of a sputtering technique that is a type of PVD, and can be used in conjunction with the systems 300, 410. At step 610, a chamber such as, but not limited to, chamber 301, may be provided that is configured to permit a partial pressure to be created therein, and configured to permit a target substrate 307 such as, e.g., glass, borosilicate glass, aluminosilicate glass, ion-exchange glass, transparent plastic, or yttria-stabilized zirconia (YSZ) to be coated.

At step 620, a source of aluminum such as, but not limited to, substantially pure aluminum, may be provided that enables energetic and unbounded aluminum atoms to be generated in the chamber 301. The aluminum target 309 is placed on a reactive magnetron sputtering device. Additionally, at step 620, a platform 308 is configured within the chamber 301 which holds the substrate 307 in place. Both the reactive magnetron sputtering device 304 and the platform 308 may be configured to be adjusted, rotated, and otherwise moved within the chamber 301. For example the platform 308 and the reactive magnetron sputtering device 304 may be configured to be moved in an x-axis, a y-axis and/or a z-axis. Further, the chamber 301 may be configured to permit the target substrate 307 and the aluminum 309 to be heated or cooled.

At step 630, aluminum oxide is generated. This is done by setting a pressure within the chamber, step 631, and setting a temperature of the substrate and/or in the chamber, step 632. Additionally, at step 633, a biasing power is provided by the reactive magnetron sputtering device 304 across the aluminum target 309 to produce a plasma of energetic ions in the chamber 301 that are drawn to the aluminum target 309 thereby releasing aluminum atoms or aluminum oxide molecules by bombardment. The surface of the aluminum target 309 may be partially or completely oxidized by the partial pressure of oxygen within the chamber 301. The aluminum atoms and/or aluminum oxide molecules may create a deposition beam 305 directed towards the substrate 307. At step 631, a partial pressure of oxygen may be created in the chamber 631. This may be achieved by permitting oxygen to flow into the chamber 301, perhaps under pressure. At step 640, the aluminum atoms and/or aluminum oxide of beam 305 reach the target substrate 307. The deposited film 306 may be formed at the surface(s) of the target substrate 307. Further, the aluminum atoms may interact with the oxygen environment as they are directed towards the substrate 307 creating aluminum oxide molecules which are also directed toward the substrate 307.

According to an exemplary embodiment, at an additional step which may be optional, a gap or distance between the aluminum target 309 and the substrate 307 may be adjusted, typically reduced but may be increased, to control the rate of depositing of the aluminum oxide film on the target substrate 307. Further, the substrate 307 may be re-positioned by adjusting the platform 308 orientation. Particularly, the platform 308 may be rotated or moved in any axis.

Further, at step 640, a thin film is permitted to be created at one or more surfaces of the substrate 307 as the aluminum atoms and/or aluminum oxide molecules coat and bond with the one or more surfaces. The process may be terminated when one or more parameters are achieved such as time, or based on a depth of the aluminum oxide formed on the substrate 307, or amount/level of oxygen pressure employed, or any combination therefore. Moreover, a user may stop the process at any time.

This sputtering process of FIG. 6 has an advantage in that it does not utilize or require separate chambers with moveable partitions or extremely high temperatures and subsequent complexities typically found in other techniques which may also be implemented. According to another exemplary embodiment, a combinational approach may be implemented where the aluminum is heated as done in the thermal approach while also providing a voltage and current across the aluminum to excite additional aluminum atoms to release.

The steps of FIG. 6 may be performed by or controlled by a computer that is configured with software programming to perform the respective steps. FIG. 6 may also represent a block diagram of the components for executing the steps thereof. The components may include software executable by a computer processor for reading the software from a physical storage (a non-transitory medium) and executing the software that is configured to performing the respective steps. The computer processor may be configured to accept user inputs to permit manual operations of the various steps described.

The processes of FIGS. 5 and 6 and the systems of FIGS. 1 through 4 may produce a matrix comprising a thin, transparent, and shatter-resistant window (i.e., the substrate 307) coated with a scratch-resistant aluminum oxide film 306 that is lightweight, has superior resistance to breakability and has a thickness of about 2 mm or less. The thin window (i.e., the matrix combination of the deposited scratch-resistant aluminum oxide film and transparent and shatter-resistant substrate) is configured and characterized as having shatter resistance with a Young's Modulus value that is less than that of sapphire, i.e., less than about 350 gigapascals (GPa). According to an exemplary embodiment, in one instance this coating may demonstrate a hardness greater than 10 GPa as measured by nanoindentation with a Berkovich probe tip. Nanoindentation may include one or more of a variety of indentation hardness tests. In another instance this coating may demonstrate a hardness greater than 14 GPa as measured by nanoindentation with a Berkovich probe tip. Further, in yet another instance this coating may demonstrate a hardness greater than 20 GPa as measured by nanoindentation with a Berkovich probe tip.

Moreover, it should be understood that, in the case that there are different values for the Young's Modulus based on a testing method or region of material tested (e.g., ion-exchange glass which may have different values for the surface and the bulk), that the lowest value is the applicable value. The thin window produced by the processes of FIGS. 5 and 6 may be used to produce thin windows for use in different devices including, e.g., watch crystals, optical lenses, and touch screens as used in, e.g., mobile phones, tablet computers, and laptop computers, where maintaining a scratch-free or break-resistant surface may be of primary importance.

Several properties including hardness, transparency, coloration which may be tuned to application, adhesion to a substrate direction or to intermediary layer can be controlled and adjusted. For example, the hard optical film/coating can be used to provide wear resistance and/or to stiffen the substrate. The hard optical film/coating can also have properties that are hydrophobic and anti-reflective. This hard optical film/coating can be alternated with another coating to tune optical properties as desired for particular applications. Additionally, the thickness can range from 100 nm through Sum. According to one embodiment, the hard optical coating can be 1 um providing optimal hardness and transparency values for certain applications. Further, the hard optical film/coating can be doped with various elements for coloration and hardness tuning. The hard optical film/coating can also be processed further to have unique textures to enhance optical and hydrophobicity/oleophobicity properties.

This hardened optically transmissive material that includes the hard optical coating made of aluminum oxide can provide a desirable hardness while being less expensive that a single crystal sapphire. Additionally, creating and depositing the hard optical coating has been developed such that it can be integrated into a current manufacturing process. Additionally, the hard optical coating can also exhibit desirable optical properties including transparency values along with a tuned color.

Thus, the hard optical coating made from aluminum oxide can provide high levels of transparency and hardness at low temperature deposition compatible with low cost substrates such as glass or plastics. Costs are low in part because of the deposition rates and techniques (PVD) to allow for the creation and placement of the hard optical coating are relatively cheap in relation to more expensive alternatives. According to one or more embodiments, the lifetime of a product using the hard optical coating can be increased. Also it is possible to integrate several separate coatings of the hard optical coating into one coating while maintaining relatively low cost compared to single crystal sapphire, gorilla glass, and/or diamond like coatings while providing higher performance than other alumina or aluminum coatings with lower hardness, laminates that are bonded to the substrate; and other coating and alternatives. Additionally, the hard optical coating and associated methods as disclosed can be adapted for many applications because it can be made and controlled to provide a specific hardness, transparency/color, thickness, roughness, adhesion, young's modulus, and weathering resistance.

Other examples are provided herewith which are in line with the exemplary embodiments described above. One example is a device that includes a hard and transparent coating that is applied directly to a substrate via a sputtering deposition method. This coating is comprised predominantly of aluminum oxide (Al2O3). This coating exhibits transparency such that when light waves having wavelengths greater than 400 nm and less than 900 nm are irradiated on the surface of the coating at an angle that is orthogonal to the coating surface, a minimum of 84 percent of the light waves are transmitted through the device. According to another embodiment, a minimum of 84 percent of the light waves are transmitted through the device for light waves with a wavelength between 900 nm and 3300 nm.

Another example includes a device that applies a hard and transparent coating directly to a substrate via a thermal deposition method. This hard optical coating is comprised predominantly of aluminum oxide (Al2O3). This coating exhibits transparency such that when light waves having wavelengths greater than 400 nm and less than 900 nm are irradiated on the surface of the coating at an angle that is orthogonal to the coating surface, a minimum of 84 percent of the light waves are transmitted through the device According to another embodiment, a minimum of 84 percent of the light waves are transmitted through the device for light waves with a wavelength between 900 nm and 3300 nm.

According to another example, a hard optical coating that is transparent to infrared light is applied directly to a substrate via a sputtering deposition method. This coating is comprised predominantly of aluminum oxide (Al2O3). This hard optical coating exhibits transparency such that when light waves having wavelengths greater than 900 nm are irradiated on the surface of the coating at an angle that is orthogonal to the coating surface, a minimum of 84 percent of the light waves are transmitted through the device. According to another embodiment, a minimum of 84 percent of the light waves are transmitted through the device for light waves with a wavelength between 900 nm and 3300 nm.

According to one or more examples, the hard optical coating demonstrates a hardness greater than 10 GPa, a hardness greater than 14 GPa, or a hardness greater than 20 GPa as measured by nanoindentation with a Berkovich probe tip.

Further, according to one or more examples, transparency is achieved through strong control over stoichiometry such that the ratio of aluminum atoms in the deposited coating/film is controlled to a 2x:3 ratio with oxygen atoms, where ‘x’ is between 0.95 and 1.05. The vapor deposition of the aluminum atoms and the oxygen atoms is at a two to three ratio, respectively, with a ratio variance of less than or equal to 5%. The ratio can be maintained by adjusting the partial pressure of oxygen into the chamber during deposition, as well as by tuning the deposition rate, for example a sputtering rate, from the alumina or aluminum source material/targets by modifying the biasing power and/or temperature to the alumina or aluminum targets. This can be done while sputtering or by modifying the heating power of the source material while depositing by a thermal method. In the case of a non-DC biasing during sputter deposition, further tuning of the oxygen flow may be provided to accommodate the variability of deposition resulting from the non-constant voltage bias.

Additional control of transparency can be achieved through control of impurities imparted to the system. Methods for achieving this include control over the purity of materials and source gases as well as proper chamber design. For example, the material for the chamber structure, and particularly for regions of the chamber near the deposition area, can be made from a material such as stainless steel that is inert to an oxidizing environment. For example, stainless steel having a low nickel content may be used in place of other materials within the heating assembly, thereby mitigating oxidizing effects.

In one example the transparent hard optical coating includes a small fraction of foreign atoms such as e.g. gallium, indium, or carbon that are intentionally introduced during growth, or through a diffusion process after growth, in order to strengthen the hard optical coating made from aluminum oxide over what would be possible without the introduction of these atoms.

According to an example the aluminum-oxide that makes up the hard optical coating exists predominantly in the corundum crystal structure.

According to another example, a hard optical coating that is a transparent coating is adhered to a substrate via deposition onto an intermediary layer in order to permit adhesion of the transparent layer to the substrate and where the transparent layer is comprised predominantly of aluminum oxide (Al2O3). The intermediary layer is comprised of a metal oxide such as e.g. magnesium-oxide, chromium-oxide or nickel-oxide and may be 100-200 nm thick or less. The transparent layer is applied via a physical deposition method such as e.g. sputtering or thermal evaporation. This hard optical coating exhibits transparency such that when light waves having wavelengths greater than 400 nm and less than 900 nm are irradiated on the surface of the coating at an angle that is orthogonal to the coating surface, a minimum of 84 percent of the light waves are transmitted through the device According to another embodiment, a minimum of 84 percent of the light waves are transmitted through the device for light waves with a wavelength between 900 nm and 3300 nm.

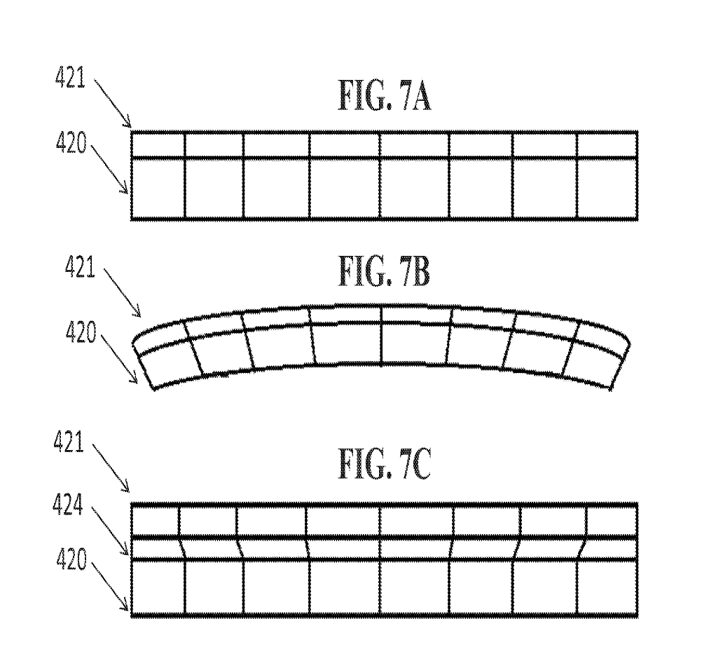

Additionally, in accordance with one or more exemplary embodiments, and as shown in FIGS. 7A through 7C, an intermediary layer 424 can provide structural buffering between the aluminum oxide coating 421 and the substrate 420. Particularly, the intermediary layer 424 may be comprised of materials, elements, or a crystal structure that allows for a reduction in the stress of the aluminum-oxide layer 421 over what would be otherwise possible. Further, the intermediary layer 424 may be selected based on its coefficient of thermal expansion (CTE). Specifically, the material may be chosen to have a CTE value that is in-between the values of the substrate 420 and the aluminum oxide coating/film 421. Alternatively, according to another embodiment, the material may be selected such that a compensating CTE intermediary layer 424 is provided between the layers 420, 421. The compensating CTE has a CTE value that is either larger than both the aluminum oxide layer 421 and the substrate 420 or is smaller than both the aluminum oxide layer 421 and the substrate 420.

Thus, when the intermediary layer 424 is in place between the hard optical coating 421 and the substrate 420 the intermediary layer 424 serves as a buffer that helps mitigate the issue of depositing the layers at deposition temperatures that cause the layers to expand by different amounts causing a curvature to form upon cooling and/or layer separation. By placing the intermediary layer 424 between the other two layers it can serve as a buffer to help avoid/mitigate the effects of the variants in CTE between the hard optical coating 421 and the substrate 420.

For example, in FIG. 7A an aluminum oxide film 421 is shown at the time of deposition on the substrate 420. The temperature at the time of deposition is higher than room temperature. Further, the CTE of the aluminum oxide film 421 is lower than the CTE of the substrate 420. Thus, at the time of deposition the substrate 420 has expanded more than the aluminum oxide film that is being deposited on the substrate. Accordingly, as shown in FIG. 7B, at room temperature, the substrate 420 and the aluminum oxide film 421 have cooled and constricted back to their respective room temperature states. However, because of the difference between the CTE values of each material, when they constrict back the substrate 420 does so more than the aluminum oxide film 421 causing stress between the layers and a warped bent shape to occur. Alternatively, it is possible that the warping and bending does not show however the stress will remain present between the layers possibly causing eventual separation of the layers as well as structural fatigue of the materials over time. However, by introducing an intermediary layer 424 between the substrate 420 and the aluminum oxide film 421 the above discussed stress, warping, and bending can be mitigated. This is done by selecting an intermediary later 424 that has a CTE that falls between that of the aluminum oxide film 421 and the substrate 420. Alternatively, the CTE may be lower than both the CTE values of both the aluminum oxide film 421 and substrate 420 or may be higher than both the CTE values of the aluminum oxide film 421 and substrate 420 thereby providing a compensating CTE intermediary layer. Accordingly, the intermediary layer 424 can be chosen to have a CTE that upon cooling of the substrate to room temperature will result in the intermediary layer 424 being under a state of compressive stress. The use of a compressively stressed layer may increase the strength of the overall device. This compressively stressed layer may be applied to both sides of the device, such as a display, to further enhance the strengthening effect.

According to one or more embodiments, the intermediary layer is comprised of materials or elements that allow for the aluminum-oxide coating to be grown predominantly in a desired crystal structure or orientation. For example, the intermediary layer is chosen to have lattice parameters similar to that of corundum-phase alumina in a specific orientation, such as the [0001] orientation. In this instance the intermediary layer influences the structure of the deposited alumina film, thereby allowing control of the structure and orientation of the alumina.

According to one or more embodiments, the intermediary layer is applied for aesthetic purposes and is applied to some regions of the substrate surface. For example, a paint may be applied the outer edges of the substrate to create an aesthetic bezel. The intermediary layer may be comprised of several individual layers.

Further, the intermediary layer may be comprised of a transparent and conductive layer, such as indium-tin-oxide (ITO) or zinc-oxide (ZnO). This conducting layer may be used for additional functionality of the display, such as for touch controls.

In another example, the intermediary layer can be chosen to act as a surfactant in the deposition process. In this case the intermediary layer may alter the surface energy of the substrate, thereby altering the growth mode and subsequent properties of the alumina film, also called the aluminum oxide film/coating. For example, a specific surfactant may be utilized to alter growth from island formation to layered growth.

According to another example, a transparent hard optical coating made up of predominantly of aluminum oxide (Al2O3) can be applied to non-transparent surfaces in order to create a clear scratch-proof surface. This coating can exhibit transparency such that when light waves having wavelengths greater than 400 nm and less than 900 nm are irradiated on the surface of the coating at an angle that is orthogonal to the coating surface, a minimum of 84 percent of the light waves are transmitted through the device. According to another embodiment, a minimum of 84 percent of the light waves are transmitted through the device for light waves with a wavelength between 900 nm and 3300 nm.

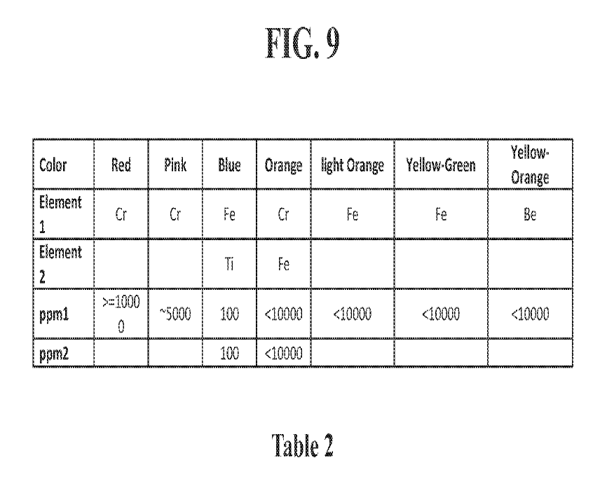

According to one or more exemplary embodiments, a hard optical coating that may be translucent or opaque and is made up of predominantly aluminum oxide (Al2O3) can be applied to a non-transparent surface in order to create a colored scratch-proof surface wherein the coating includes a small percentage of foreign atoms such as e.g. chromium (Cr), titanium (Ti), iron (Fe), beryllium (Be), or carbon (C). These atoms are intentionally introduced in order to alter the coloration of the coating. The foreign atoms (i.e. dopants) may be introduced during growth or may be diffused into the coating post growth. For example, particular exemplary embodiments of dopants and the corresponding colors they create are set out in Table 2 shown in FIG. 9. Particularly, the specific elements and their corresponding parts per million (ppm) amounts are shown which create the disclosed colors.

The particular elements introduced as dopants in the system may be selected based on their ability to be incorporated into the alumina matrix at the desired concentration. They may also be selected to achieve a specific stress profile in the material.

Doping atoms may be introduced during deposition by modification the aluminum targets to have impurities in the desired homogenous ratio with aluminum atoms or by the introduction of the dopant atoms from an alternative vapor source such as an additional sputtering target, an electron-beam heated target, an effusion cell, or any other method of producing a metallic vapor within the chamber during deposition.

Doping may also be achieved by the flow of gases containing the desired doping elements into the chamber during growth. An example may be the introduction of small amounts of methane into the chamber during growth wherein the methane is allowed to decompose into carbon and reactive hydrogen during deposition thereby permitting the inclusion of carbon into the resultant hard optical film/coating.

A third way of achieving the desired doping profile in the film may be through diffusion and performed post-growth. In this case, a gas containing the desired doping elements may be introduced into a chamber while the substrate is maintained at an elevated temperature. Additional gasses may be introduced so as to produce a chemical reaction in the chamber. For example, methane and hydrogen may be introduced into the chamber. The two gasses may react producing gaseous carbon and hydrogen. The carbon may then diffuse into the substrate by thermal processes thereby creating a non-constant doping profile across the substrate.

According to an exemplary embodiment, a hard optical coating that is transparent and is made predominantly of aluminum oxide (Al2O3) is adhered to a non-transparent substrate via deposition onto an intermediary layer in order to permit adhesion of the transparent layer to the substrate and where the transparent layer is comprised predominantly of aluminum oxide (Al2O3). The intermediary layer may be comprised of a metal oxide such as e.g. magnesium-oxide, chromium-oxide or nickel-oxide and may be 100-200 nm thick or less. The transparent layer may be applied via a physical deposition method such as e.g. sputtering or thermal evaporation. This coating is to exhibit transparency such that when light waves having wavelengths greater than 400 nm and less than 900 nm are irradiated on the surface of the coating at an angle that is orthogonal to the coating surface, a minimum of 84 percent of the light waves are transmitted through the device. According to another embodiment, a minimum of 84 percent of the light waves are transmitted through the device for light waves with a wavelength between 900 nm and 3300 nm. In one embodiment the intermediary layer may be comprised of materials or elements that allow for the aluminum-oxide coating to be grown predominantly in a desired crystal structure or orientation. In one embodiment the intermediary layer may be comprised of materials, elements, or crystal structure that allows for a reduction in the stress of the aluminum-oxide layer over what would be otherwise possible.

According to another exemplary embodiment, a hard optical coating that is translucent or opaque is predominantly made of aluminum oxide (Al2O3) and is adhered to a non-transparent surface via an intermediary layer in order to create a colored scratch-proof surface wherein the coating includes a small percentage of foreign atoms such as e.g. chromium, titanium, iron, beryllium or carbon and these atoms are intentionally introduced in order to alter the coloration of the coating. The foreign atoms (i.e. dopants) may be introduced during growth or may be diffused into the coating post growth. The intermediary layer may be comprised of a metal oxide such as e.g. magnesium-oxide, chromium-oxide or nickel-oxide and may be 100-200 nm thick or less. The transparent layer may be applied via a physical deposition method such as e.g. sputtering or thermal evaporation.

According to one or more embodiments, the deposition process may be modified in order to make the hard optical coating/films more rigid. By doing so, the films may be utilized to improve the rigidity of the overall display. The coating may be applied to both sides of the substrate to enhance this effect. In doing so, it may be possible to make displays that are much thinner without any sacrifice to the structural integrity of the display. This may be particularly advantageous if the display is intended to provide structural support to the device (such as a cell phone) that is utilizing the display.

According to one or more embodiments, the applied alumina coating may be a polycrystalline film. The structure of the crystal domains may be predominantly corundum alumina. The polycrystalline nature of the film may offer advantages over a single-crystal corundum film. One such advantage is that the polycrystalline film may be less brittle than single crystal corundum alumina. As a result the film may be less prone to breakage or other mechanical failure.

Moreover, the size of the crystal domains may be controlled through process modifications in order to maintain a preferred range of domain sizes. For example, the domains may be controlled such that the individual domains are smaller than several hundred nanometers across in any direction, thereby allowing for improved optical performance of the deposited film.

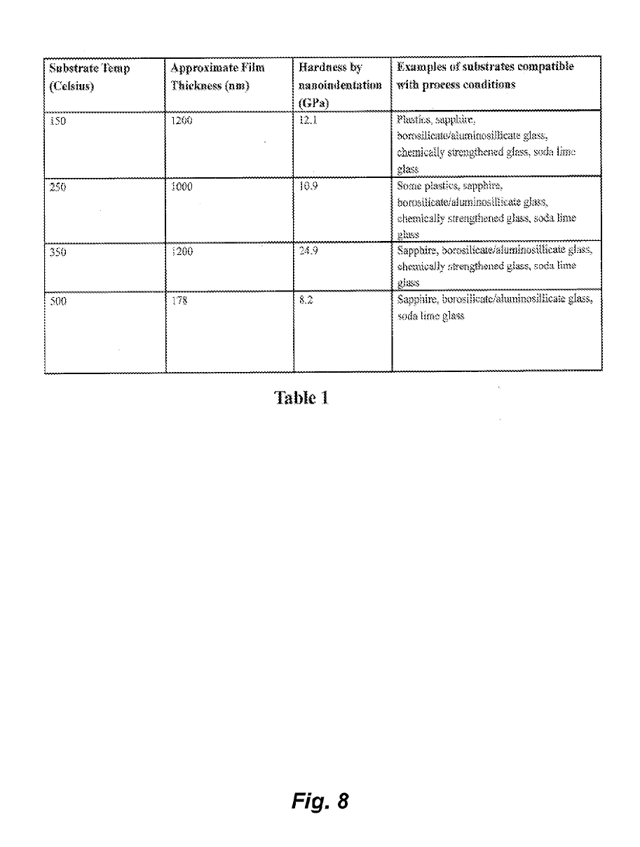

In accordance with one or more embodiments, the properties of the deposited film are directly related to temperature and film thickness. For example, as shown in Table 1 of FIG. 8, this relationship is demonstrated in multiple disclosed embodiments. Particularly, substrates that are compatible with process conditions that include a substrate temperature of 150° C. (Celsius), a film thickness of 1200 nm, and a GPa of 12.1 include plastics, sapphire, borosilicate/aluminosilicate glass, chemically strengthened glass, soda lime glass. Substrates that are compatible with process conditions that include a substrate temperature of 250° C., a film thickness of 1000 nm, and a GPa of 10.9 include some plastics, sapphire, borosilicate/aluminosilicate glass, chemically strengthened glass, soda lime glass. Substrates that are compatible with process conditions that include a substrate temperature of 350° C., a film thickness of 1200 nm, and a GPa of 24.9 include sapphire, borosilicate/aluminosilicate glass, chemically strengthened glass, soda lime glass. Substrates that are compatible with process conditions that include a substrate temperature of 500° C., a film thickness of 178 nm, and a GPa of 8.2 include sapphire, borosilicate/aluminosilicate glass, and soda lime glass.

According to one or more embodiments, maximizing hardness in general may require the use of high substrate temperatures. However, high temperature may not be compatible with all substrate materials. For example, temperatures above 400° C. can damage mechanical properties of chemically-strengthened glass by damaging the ion exchange layer, and temperatures above 200° C. are incompatible with certain plastics due to their melting temperatures. Thus, temperature and hardness can be optimized for a given material. The use of the aforementioned techniques may increase the mobility of deposited atoms/molecules on the surface of the substrate thereby facilitating the deposition of alumina films with the desired properties.

While the disclosure has been described in terms of examples, those skilled in the art will recognize that the disclosure can be practiced with modifications in the spirit and scope of the appended claims. These examples are merely illustrative and are not meant to be an exhaustive list of all possible designs, embodiments, applications or modifications of the disclosure. Accordingly, the scope should be limited only by the attached claims.

1. A structure for a hardened optically transmissive material including a hard coating, the structure comprising:
a substrate; and
an aluminum oxide film disposed over the substrate,
wherein the aluminum oxide film is grown to between 100 nanometers (nm) and 5 microns (um);
wherein the aluminum oxide film demonstrates a hardness greater than 10 gigapascals (GPa) as measured by nanoindentation; and
wherein the aluminum oxide film exhibits a transparency value such that at least 84 percent of light waves transmit through the aluminum oxide film for infrared light waves within a range of wavelengths from about 900 nm to about 3300 nm.

2. The structure including the hard coating of claim 1, wherein the substrate is non-transparent.

3. The structure including the hard coating of claim 1, wherein the aluminum oxide film disposed over the substrate is done by vapor deposition of aluminum atoms with oxygen atoms.

4. The structure including the hard coating of claim 1, further comprising:
an intermediary layer disposed between the aluminum oxide film and the substrate.

5. The structure including the hard coating of claim 4, wherein the intermediary layer is selected from a group consisting of a transparent conductor, a bezel paint, and a combination thereof.

6. The structure including the hard coating of claim 4, wherein the intermediary layer is structured such that the aluminum oxide film grows on the intermediary layer with a crystal structure and a preferred orientation of [0001].

7. The structure including the hard coating of claim 4, wherein the intermediary layer has a Coefficient of Thermal Expansion (CTE) that is between CTE values of the substrate and the aluminum oxide film.

8. The structure including the hard coating of claim 4, wherein the intermediary layer has a compensating Coefficient of Thermal Expansion (CTE) that is lower than CTE values of the substrate and the aluminum oxide film.

9. The structure including the hard coating of claim 4, wherein the intermediary layer has a compensating Coefficient of Thermal Expansion (CTE) that is higher than CTE values of the substrate and the aluminum oxide film.

10. The structure including the hard coating of claim 4, wherein the intermediary layer is a metal oxide, and wherein the intermediary layer is between 100 nm and 200 nm thick.

11. The structure including the hard coating of claim 10, wherein the intermediary layer is a metal oxide selected from a group consisting of titanium-oxide, zinc-oxide, magnesium-oxide, chromium-oxide, and nickel-oxide.

12. The structure including the hard coating of claim 3,
wherein the vapor deposition used is one selected from a group consisting of physical vapor deposition (PVD) and chemical vapor deposition (CVD),
wherein PVD includes at least cathodic arc deposition, electron beam physical vapor deposition, evaporative deposition, pulsed laser deposition, sputtering deposition, and thermal deposition, and
wherein CVD includes at least atmospheric pressure CVD (APCD), low-pressure CVD (LPCVD), ultrahigh vacuum CVD (UHVCVD), aerosol assisted CVD (AACVD), direct liquid injection CVD (DLICVD), microwave plasma-assisted CVD (MPCVD), plasma-enhanced CVD (PECVD), atomic-layer CVD (ALCVD), combustion CVD (CCVD), hot filament CVD (HFCVD), hybrid physical-chemical CVD (HPCVD), metalorganic CVD (MOCVD), rapid thermal CVD (RTCVD), vapor-phase epitaxy (VPE), and photo-initiated CVD (PICVD).

13. The structure including the hard coating of claim 3, wherein the vapor deposition of the aluminum atoms and the oxygen atoms is at a two to three ratio, respectively, with a ratio variance of less than or equal to 5%.

14. The structure including the hard coating of claim 3, wherein the vapor deposition of the aluminum atoms and the oxygen atoms is at a two to three ratio, respectively, with a ratio variance of less than or equal to 10%.

15. The structure including the hard coating of claim 1, wherein the substrate is selected from a group consisting of sapphire, soda lime glass, aluminosilicate glass, borosilicate glass, Yttria-stabilized zirconia (YSZ), quartz, and a combination thereof.

16. The structure including the hard coating of claim 1, wherein the substrate is selected from a group consisting of a metal, a plastic, a metal alloy, steel, aluminum, titanium, and a combination thereof.

17. (canceled)

18. (canceled)

19. The structure including the hard coating of claim 1, wherein the aluminum oxide film is grown to 1 um.

20. The structure including the hard coating of claim 1, wherein the aluminum oxide film demonstrates a hardness greater than 14 gigapascals (GPa), and wherein the hardness is measured by nanoindentation with a Berkovich probe tip.

21. The structure including the hard coating of claim 1, wherein the aluminum oxide film demonstrates a hardness greater than 20 gigapascals (GPa), and wherein the hardness is measured by nanoindentation with a Berkovich probe tip.

22. The structure including the hard coating of claim 1, further comprising:
foreign dopant atoms mixed into the aluminum oxide film that strengthen the hard coating,
wherein the foreign dopant atoms are selected from a group consisting of gallium, indium, carbon, and a combination thereof.

23. The structure including the hard coating of claim 1, further comprising:
foreign dopant atoms mixed into the aluminum oxide film that adjust a coloration of the aluminum oxide film,
wherein the foreign dopant atoms are selected from a group consisting of chromium, titanium, iron, beryllium, carbon, and a combination thereof.

24. The structure including the hard coating of claim 1, wherein the aluminum oxide film forms in a corundum crystal structure.

25. A method of creating a hard coating, the method comprising:
generating aluminum oxide by setting a chamber pressure, setting a substrate temperature, creating a partial pressure of a gas in the chamber, and exposing a target within the chamber to an ionized gas;
depositing aluminum oxide by vapor deposition over a substrate in the chamber; and
stopping the vapor deposition of the aluminum oxide once an aluminum oxide film disposed over the substrate is between 100 nm and 5 um,
the aluminum oxide film having a transparency value such that at least 84 percent of infrared light waves having wavelengths from about 900 nm to about 3300 nm transmit through the aluminum oxide film.

26. The method of claim 25,
wherein the ionization is facilitated by at least one selected from a group consisting of a biasing power, a gas, a high temperature, and a combination thereof,
wherein the target is one selected from a group consisting of an aluminum target and an aluminum oxide target,
wherein the gas is one selected from a group consisting of an inert gas, a noble gas, oxygen gas, argon gas, and a combination thereof.

27. The method of claim 25, wherein depositing aluminum oxide by vapor deposition over the substrate comprises:
adjusting the partial pressure of the gas in the chamber during vapor deposition, wherein the gas is oxygen;
tuning a sputtering rate of particles from the target by modifying the ionization near the target; and
controlling the partial pressure of the oxygen and the sputtering rate of particles to achieve a ratio of two aluminum atoms for every three oxygen atoms.

28. The method of claim 25, further comprising:
depositing the aluminum oxide film over an intermediary layer disposed between the substrate and the aluminum oxide film,
wherein the intermediary layer is a metal oxide,
wherein the intermediary layer is between 100 nm and 200 nm thick,
wherein the intermediary layer has a coefficient of thermal expansion (CTE) that is different from CTE values of the substrate and the aluminum oxide film, and
wherein the intermediary layer is structured such that the aluminum oxide film grows on the intermediary layer with a crystal structure and a preferred orientation of [0001].

29. The method of claim 28, wherein the intermediary layer is a metal oxide selected from a group consisting of titanium-oxide, zinc-oxide, magnesium-oxide, chromium-oxide, nickel-oxide, and a combination thereof.

30. The method of claim 25, further comprising:
tuning the partial pressure of oxygen to accommodate for variability of deposition resulting from a non-constant voltage bias.

31. A system for creating hardened optically transmissive material that includes a hard coating, the system comprising:
a chamber that creates a partial pressure of oxygen atoms;
a support device that secures a substrate within the chamber; and
an excitation device comprising a heating element and a biased current power supply,
wherein the excitation device releases energetic and unbounded aluminum atoms from an aluminum target by heating the aluminum target, and
wherein the energetic and unbounded aluminum atoms are released into the chamber creating a deposition beam that reacts with the oxygen atoms to create an aluminum oxide film over a surface of the substrate, the aluminum oxide film having a transparency value such that at least 84 percent of infrared light waves having wavelengths from about 900 nm to about 3300 nm transmit through the aluminum oxide film.

32. The system of claim 31, wherein heating the aluminum target includes applying a biased current across the heating element causing the heating element to increase in temperature heating the aluminum target.

33. The system of claim 31, wherein the chamber, support device, and excitation device are made of stainless steel.

34. A structure for a hardened optically transmissive material including a hard coating, the structure comprising:
a substrate; and
an aluminum oxide film disposed over the substrate,
wherein the aluminum oxide film is grown to between 100 nanometers (nm) and 5 microns (um);
wherein the aluminum oxide film demonstrates a hardness greater than 10 gigapascals (GPa) as measured by nanoindentation; and
wherein the aluminum oxide film exhibits a transparency such that at least 84 percent of light waves having wavelengths from about 400 nm to about 900 nm transmit through the aluminum oxide film.

35. The structure including the hard coating of claim 34, wherein the aluminum oxide film has a surface, further wherein the aluminum oxide film exhibits a transparency to at least 84 percent of light waves having wavelengths from about 400 nm to about 900 nm irradiated on the aluminum oxide film at an angle that is orthogonal to the surface of the aluminum oxide film.

36. The structure including the hard coating of claim 34, wherein the substrate is non-transparent.
